(19) United States
(12) Patent Application Publication
(10) Pub. No.: US 2025/0386551 A1
(43) Pub. Date: Dec. 18, 2025

(54) NANOSTRUCTURE TRANSISTOR WITH REDUCED CAPACITANCE

(71) Applicant: Taiwan Semiconductor Manufacturing Co., Ltd., Hsinchu (TW)

(72) Inventors: Chung-Wei HSU, Hsinchu (TW); Lung-Kun CHU, Hsinchu (TW); Shih-Hao LAI, Hsinchu (TW); Kuo-Cheng CHIANG, Hsinchu (TW); Chih-Hao WANG, Hsinchu (TW)

(21) Appl. No.: 18/920,627

(22) Filed: Oct. 18, 2024

Related U.S. Application Data
(60) Provisional application No. 63/659,169, filed on Jun. 12, 2024.

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018; H10D 30/6736

(57) ABSTRACT

An integrated circuit includes a plurality of stacked channels, a hard mask structure above the channels, and a gate metal above the hard mask structure and wrapped around the channels. The integrated circuit includes a high-K gate dielectric layer wrapped around the channels, wherein a top of the hard mask structure is higher than a top of the high-K gate dielectric layer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-25 are cross-sectional and perspective views of an integrated circuit at various stages of processing, in accordance with some embodiments.

FIGS. 26A-26E are hard mask structures of an integrated circuit, in accordance with some embodiments.

FIG. 27 is a flow diagram of a method of manufacturing an integrated circuit, in accordance with some embodiments.

FIG. 28 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the disclosure provide nanostructure transistors with reduced gate to source/drain capacitance. Embodiments of the present disclosure provide a hard mask structure above the stacked channels of a transistor. The hard nanostructures utilized to remove the high-K gate dielectric layer from sidewalls of a gate spacer layer, apart from below the hard mask structure. Furthermore, dopant atoms are implanted into dielectric structures adjacent to the gate metal to further reduce the dielectric constant of those dielectric structures. The result is that gate capacitances are greatly reduced. This further results in transistors that can operate at higher frequencies, have superior electrical characteristics, and better overall performance. Furthermore, this can improve wafer yields and overall function of integrated circuits and electronic devices in which the integrated circuits are embedded.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

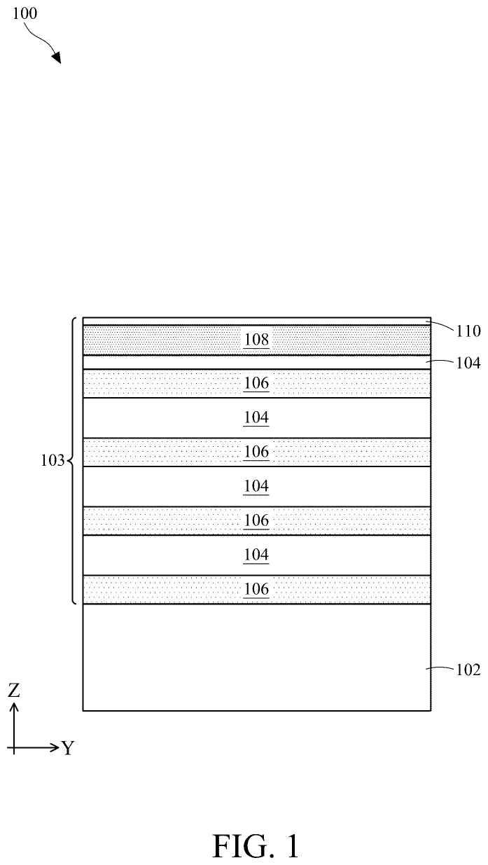

FIGS. 1-15 are cross-sectional views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. The stack 103 includes a top sacrificial semiconductor layer 108 on a highest of the semiconductor layers 106. The stack 103 includes a cap layer 110 on the top sacrificial semiconductor layer 108.

As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below. In some embodiments, the top semiconductor layer 104 is thinner than the lower three semiconductor layers 104. In some embodiments, the top semiconductor layer 104 is not used to form channel regions of a transistor.

In some embodiments, the top sacrificial semiconductor nanostructure 108 includes a semiconductor material that is selectively etchable with respect to the semiconductor layers 104 and the sacrificial semiconductor layers 106. In one example, the semiconductor layers 104 are silicon, the sacrificial semiconductor layers 106 are silicon germanium, and the top sacrificial semiconductor layer 108 is silicon germanium. In some embodiments, the sacrificial semiconductor layers 106 have a concentration of germanium between 10% and 20%, while the top sacrificial semiconductor layer 108 has a germanium concentration between 30% and 50%. This enables the sacrificial semiconductor layers 106 to be selectively etchable with respect to the semiconductor layers 104 and the top semiconductor layer 108. This also enables the top sacrificial semiconductor layer 108 to be selectively etchable with respect to the semiconductor layers 104 and the sacrificial semiconductor layers 106. Other materials and concentrations can be utilized without departing from the scope of the present disclosure.

In some embodiments, the cap layer 110 can include a semiconductor material such as silicon, silicon carbide, or other suitable materials. Alternatively, the layer 110 can include a dielectric material.

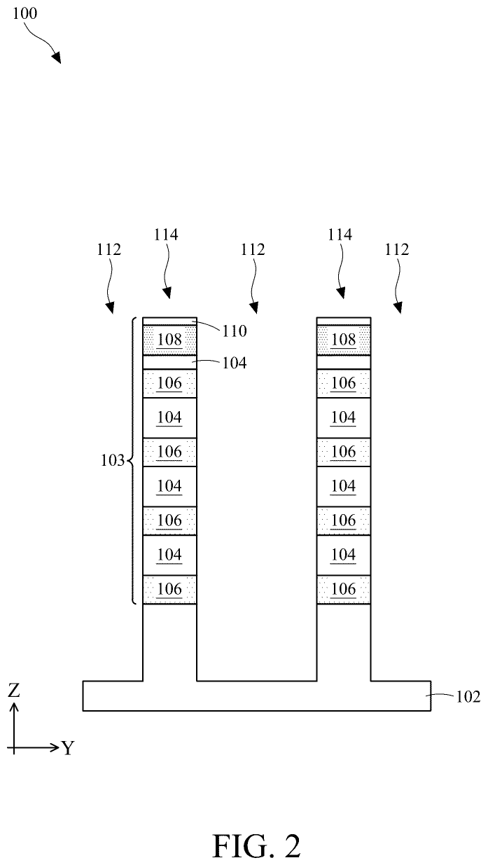

In FIG. 2, trenches 112 have been formed in the stack 103 and in the substrate 102. Though not shown in FIG. 1, a hard mask layer is first formed and patterned on the stack 103. The trenches 112 can be formed with an anisotropic etching process that etches in the downward direction in the presence of the patterned hard mask. The etching process defines semiconductor fins 114 by forming trenches 112 through the cap layer 110, the top sacrificial semiconductor layer 108, sacrificial semiconductor layers 106, the semiconductor layers 104, and the substrate 102.

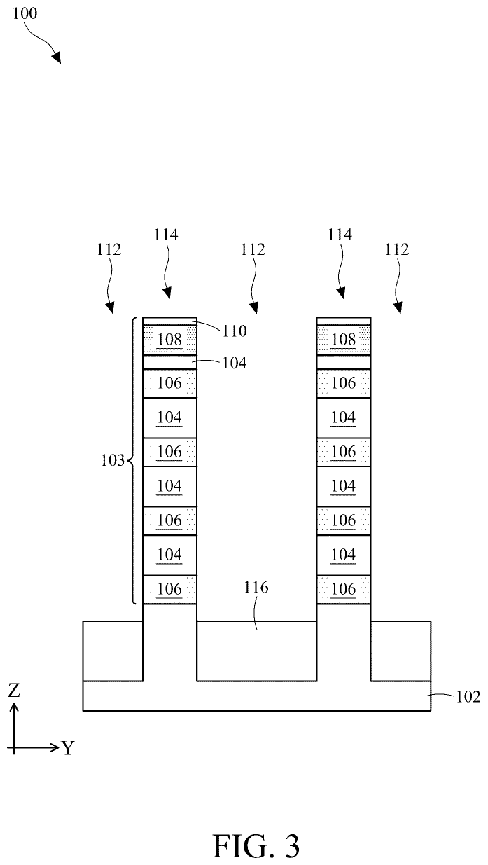

FIG. 3 is a cross-sectional Y-view, in accordance with some embodiments. In FIG. 3, shallow trench isolation regions 116 have been formed by depositing a dielectric material in the trenches 112 between fins 114. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SiN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

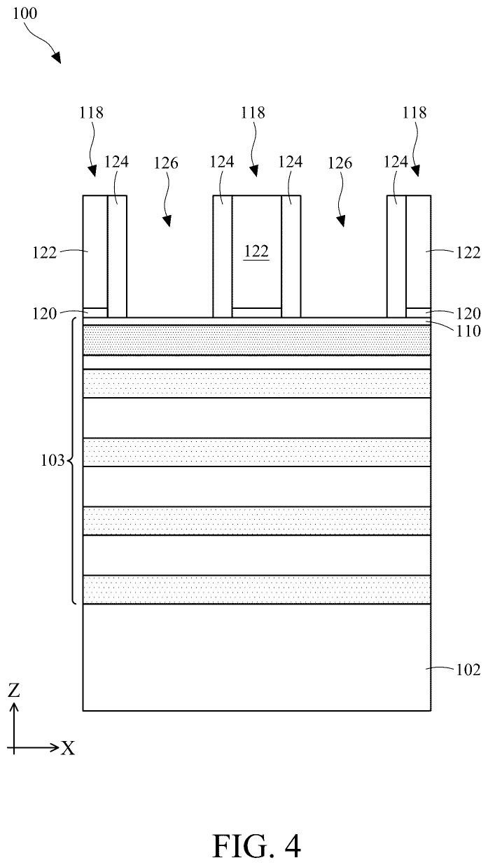

FIG. 4 is an X-view of the integrated circuit 100, in accordance with some embodiments. In FIG. 4, sacrificial gate structures 118 have been formed over the fins 114. The sacrificial gate structures 118 extend in the Y direction, perpendicular to the fins 114. In practice, each sacrificial gate structure 118 crosses multiple fins 114. The sacrificial gate structures 118 are also formed in the trenches 112.

The sacrificial gate structures 118 include a dielectric layer 120. In an exemplary embodiment, the dielectric layer 120 includes silicon oxide. However, alternatively, the dielectric layer 120 can include SiN, SiCN, SiOC, SiOCN, or other dielectric materials without departing from the scope of the present disclosure. In some embodiments, the dielectric layer 120 has a low-K dielectric material. The dielectric layer 120 can be deposited by CVD, ALD, or PVD.

The sacrificial gate structures include a sacrificial gate layer 122 on the dielectric layer 120. The sacrificial gate layer 122 can include materials that have a high etch selectivity with respect to the trench isolation regions 116. In an exemplary embodiment, sacrificial gate layer 122 includes polysilicon. However, the sacrificial gate layer 122 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 122 may be deposited by physical vapor deposition (PVD), CVD, sputter deposition, or other techniques for depositing the selected material. Though not shown in FIG. 4, in some embodiments, the sacrificial gate structures 118 may include additional dielectric layers above the sacrificial gate layer 122.

In FIG. 4, gate spacer layer 124 has been formed on the sidewalls of the sacrificial gate structures 118. In particular, the gate spacer layer 124 may be formed on sidewalls of the dielectric layer 120 and the sacrificial gate layer 122. The gate spacer layer 124 may also be formed on other exposed surfaces of the integrated circuit. The gate spacer layer 124 can be formed by PVD, CVD, ALD, or other suitable deposition processes. Following formation of the gate spacer layer 124, horizontal portions (e.g., in the X-Y plane) of the gate spacer layer 124 may be removed by an anisotropic etching process, thereby exposing upper surfaces of the fins 114 and the dielectric layer 124. After patterning of the gate spacer layers, vertically thicker portions of the gate spacer layer 124 may remain. The gate spacer layer 124 can include one or more of SiO, SiN, SiON, SiCN, SiOCN, SiOC, or other suitable dielectric materials. Though not shown in FIG. 4, in some embodiments an additional gate spacer layer or liner layer is also formed on the gate spacer layer 124. The additional gate spacer layer can include one or more of SiO, SiN, SiON, SiCN, SiOCN, SiOC, or other suitable dielectric materials.

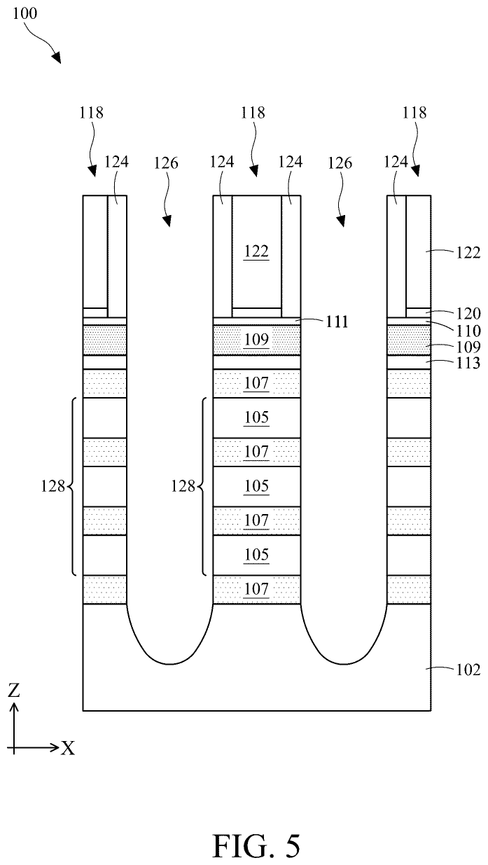

In FIG. 5, source/drain trenches 126 have been formed, in accordance with some embodiments. After patterning of the gate spacer layer 124, one or more etching processes are performed to form source/drain trenches 126 in the fins 114. Forming the source/drain trenches 126 includes etching through the cap layer 110, the top sacrificial semiconductor layer 108, each of the semiconductor layers 104, each of the sacrificial semiconductor layers 106, and a portion of the substrate 102. Accordingly, the removal operations may include suitable etch operations for removing materials of cap layer 110, the top sacrificial semiconductor layer 108, the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 126 results in formation of stacks 128 of channels 105. In particular, the remaining portions of the semiconductor layers 104 after formation of the source/drain trenches 126 now correspond to stacked channels 105 of a transistor. Formation of the source/drain trenches 126 results in formation of a plurality of sacrificial semiconductor nanostructures 107 from the sacrificial semiconductor layers 106. Formation of the source/drain trenches 126 also results in formation of the top sacrificial semiconductor nanostructures 109 from the top sacrificial semiconductor layer 108. Formation of the source/drain trenches 126 also results in formation of a cap nanostructure 111 from the cap layer 110. Formation of the source/drain trenches 126 results in formation of a top semiconductor nanostructure 113 from the top semiconductor layer 106. As described previously, the top semiconductor layer 106 is substantially thinner than the other semiconductor layers 106 and, in some embodiments, the semiconductor nanostructure 113 is not utilized as a channel 105. In some embodiments, the semiconductor nanostructure 113 is used as a channel 105.

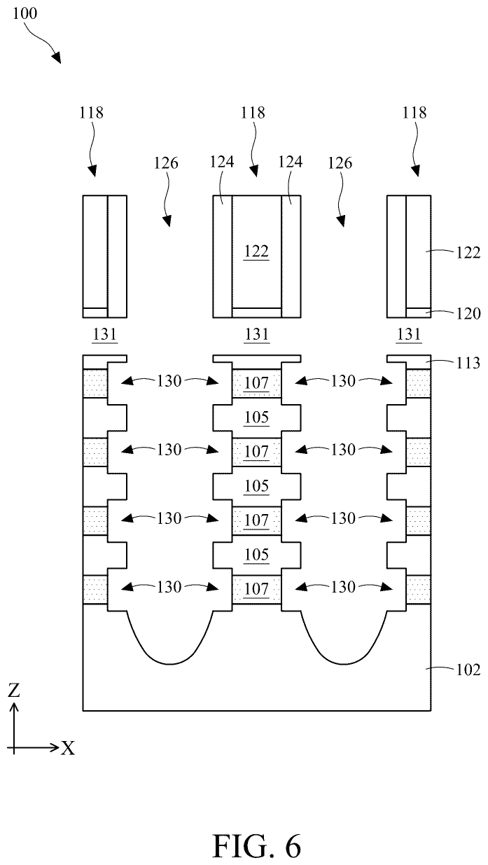

In FIG. 6, a selective etching process is performed to recess exposed end portions of the sacrificial semiconductor nanostructures 107 without substantially etching the channels 105. More particularly, recesses 130 are formed in the sacrificial semiconductor nanostructures 107 between adjacent channels 105, or between the lowest channel 105 and the substrate 102. The recesses 130 can be formed by performing an etching process that selectively etches the material of the sacrificial semiconductor nanostructures with respect to the material of the channels 105 and the substrate 102. Recesses 113 are also formed between the top channel 105 and the semiconductor nanostructure 113. In some embodiments, the process to form recesses 130 is skipped as in some cases the inner spacers, described further below, are not formed.

In FIG. 6, the top sacrificial semiconductor nanostructures 109 have been entirely removed. As described previously, the material of the top sacrificial semiconductor nanostructures 109 is selectively etchable with respect to the material of the sacrificial semiconductor nanostructures 107. Accordingly, the etching process utilized to recess the semiconductor nanostructures 107 results in the complete removal of the top sacrificial semiconductor nanostructure 107. The result is a gap 131 or void formed between the semiconductor nanostructure 113 and the sacrificial gate structure 118.

In some embodiments, the etching process that forms the recesses 130 also etches the channels 105, though at a much lower rate than the sacrificial semiconductor nanostructures 107. The result is that the ends of the channels 105 are notched. Accordingly, a middle portion of the channels 105 is vertically thicker than end portions of the channels 105. Similarly, a middle portion of semiconductor nanostructure 113 is vertically thicker than end portions of the semiconductor nanostructure 113.

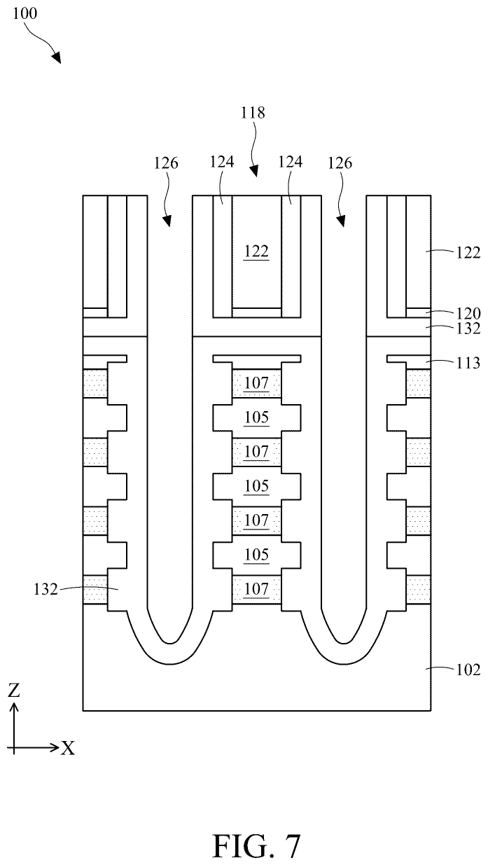

In FIG. 7, a dielectric layer 132 has been deposited. The dielectric layer has been deposited in a conformal deposition process on exposed surfaces of the channels 105, the gate spacer layer 124, the dielectric layer 130, the semiconductor nanostructure 113, the sacrificial semiconductor nanostructures 107, and the substrate 102. Most notably, the dielectric layer 132 fills the recesses 130 and the gap 131. The dielectric layer 132 can include SiCN, SiOCN, SiON, SiN, or other suitable dielectric materials. The dielectric layer can be formed by a suitable deposition method such as CVD, ALD, PVD, or other deposition processes.

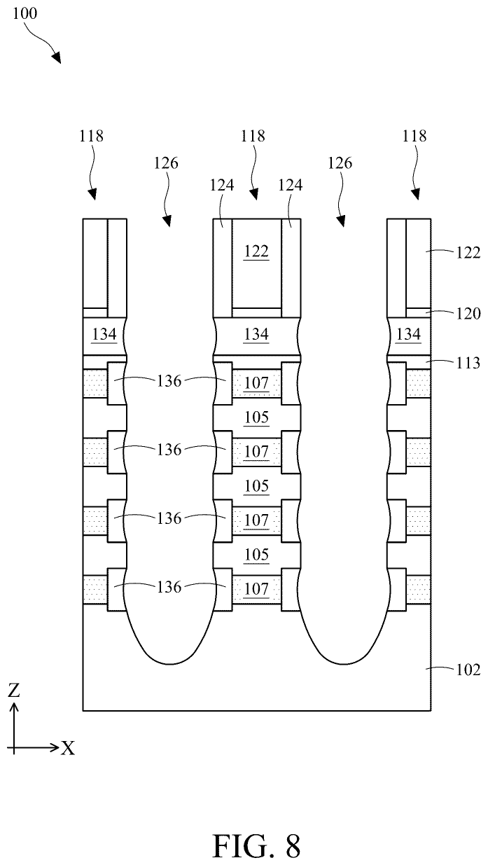

In FIG. 8, hard mask structures 134 have been formed from the dielectric layer 132 in the gaps 131 between the semiconductor nanostructures 113 and the sacrificial gate structures 118. More particularly, an etching process has been performed on the dielectric layer 132. The etching process removes the material of the dielectric layer 132 from all locations not covered by the gate spacer layer 124. Accordingly, the etching process can include an anisotropic etching process that etches in the downward direction.

In FIG. 8, inner spacers 136 have also been formed in the recesses 130. The inner spacers 136 are in contact with ends of the sacrificial semiconductor nanostructures 107 and with the channels 105. The top inner spacers 136 are also in contact with the semiconductor nanostructure 113. The top inner spacers 136 are separated from the hard mask layer 134 by the semiconductor nanostructure 113. The inner spacers 136 and the hard mask structures 134 are remnants of the dielectric layer 132.

In some embodiments, the exposed side surfaces of the inner spacers 136 and the hard mask structures 134 are concave. This can be a result of the etching process not being completely anisotropic.

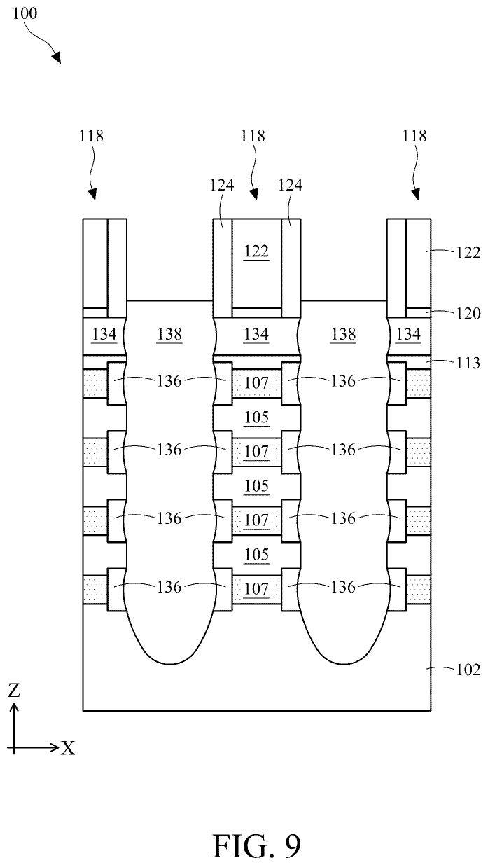

In FIG. 9, source/drain regions 138 have been formed in the source/drain trenches 126, in accordance with some embodiments. The source/drain regions 138 are epitaxially grown from the channels 105. The source/drain regions 138 are grown on exposed portions of the fins 114 and contact the channels 105. For each stack 128 of channels 105, there are two source/drain regions 138. Some stacks 128 of channels 105 may share a source/drain 138 with a stack 128 of channels 105 that is adjacent in the X direction. In FIG. 9, the source/drain regions 138 have a top surface that is higher than the top surface of the hard mask structures 134. However, in practice, the source/drain regions 138 may have top surfaces than other higher or lower than shown in FIG. 9.

The source/drain regions 138 may include any acceptable semiconductor material, such as appropriate for N-type or P-type devices. For N-type regions, the source/drain regions 138 include materials exerting a tensile strain in the channel regions, such as silicon, SiC, SiCP, SiP, or the like, in some embodiments. For P-type transistors, the source/drain regions 138 include materials exerting a compressive strain in the channel regions, such as SiGe, SiGeB, Ge, GeSn, or the like, in accordance with some embodiments. The source/drain regions 138 may have surfaces raised from respective surfaces of the fins and may have facets. Neighboring source/drain regions 138 may merge in some embodiments to form a singular source/drain region 138 over two neighboring fins of the fins 114.

In some embodiments, an in-situ doping process may be performed during formation of the source/drain regions 138 to implant to the source/drain regions 138 with N-type dopants or P-type dopants, depending on the conductivity type of the transistor or region being formed. The N-type dopants can include phosphorus, arsenic, antimony, or other suitable N-type dopants species. The P-type dopants can include boron, gallium, indium, or other suitable P-type dopants species. The source/drain regions 138 may be implanted with dopants followed by an annealing process. The source/drain regions 138 may have an impurity concentration of between about 10¹⁹ cm⁻³ and about 10²¹ cm⁻³.

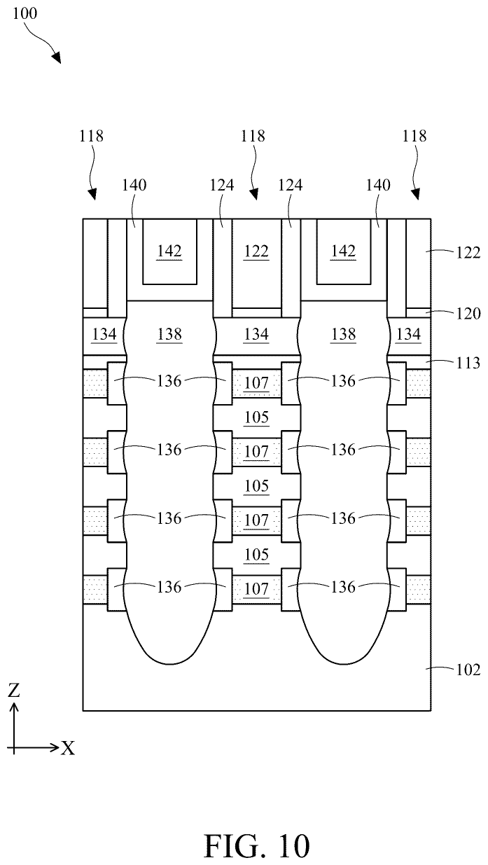

In FIG. 10, a contact etch stop layer (CESL) 140 and an interlevel dielectric (ILD) 142 have been formed, in accordance with some embodiments. The CESL layer 140 can include a thin dielectric layer conformally deposited on exposed surfaces of the source/drain regions 138, the gate spacer layers 124, and on other exposed surfaces. The CESL layer 140 can include SiN, SiC, SiOC, SiOCN, SiON, or other suitable dielectric materials. The CESL 140 can be deposited by CVD, ALD, PVD, or other suitable deposition processes.

The interlevel dielectric layer 142 covers the CESL 140. The interlevel dielectric layer 142 fills the remaining spaces between adjacent sacrificial gate structures 118. The interlevel dielectric layer 142 may correspond to a lowest interlevel dielectric layer of the integrated circuit 100. In some embodiments, the interlevel dielectric layer 142 may be termed ILD0. Though not shown herein, additional interlevel dielectric layers may be formed over the interlevel dielectric layer 142. A network of conductive vias and metal lines may be formed in the upper interlevel dielectric layers. The interlevel dielectric layer 142 can include SiO, SiON, SiN, SiC, SiOC, SiOCN, SiON, or other suitable dielectric materials. The interlevel dielectric layer 142 can be deposited by CVD, ALD, PVD, or other suitable deposition processes.

In some embodiments, a CMP process is performed after deposition of the interlevel dielectric layer 142. The result of the CMP process is that the top surfaces of the interlevel dielectric layer 142, the CESL layer 140, the gate spacer layer 124, and the sacrificial gate layer 122 are coplanar. The CMP process may also reduce the height of the sacrificial gate structures 118.

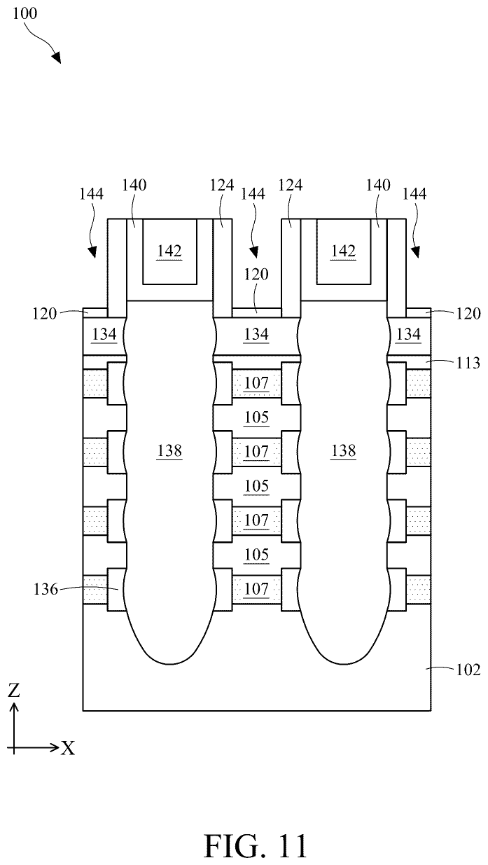

In FIG. 11, the sacrificial gate layer 122 has been removed, in accordance with some embodiments. The sacrificial gate layer 122 can be removed by an etching process that selectively etches the material of the sacrificial gate layer 122 with respect to adjacent materials, such as the dielectric layer 120 and the gate spacer layers 124. Removal of the sacrificial gate layer 122 results in gate trenches 144 between the gate spacer layers 124.

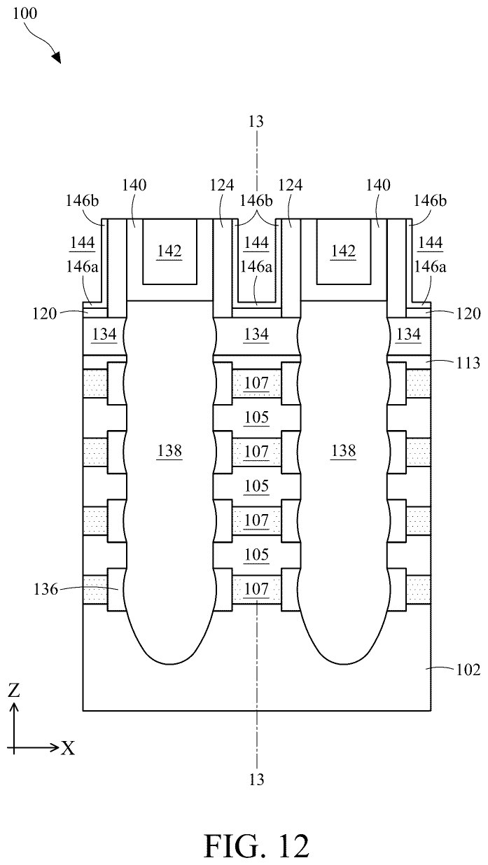

In FIG. 12, a dielectric layer 146 has been deposited, in accordance with some embodiments. The dielectric layer 146 is conformally deposited on exposed surfaces including on the dielectric layer 120 the gate spacer layer 124, and other exposed surfaces. In some embodiments, the dielectric layer 146 includes silicon nitride. Alternatively, the dielectric layer 146 can include SiCN, SiON, SiOCN, or other suitable dielectric materials.

In FIG. 12, the dielectric layer 146 includes a portion 146a and a portion 146b. The portion 146a is formed on the portions of the dielectric layer 120 that were exposed by removal of the sacrificial gate layer 122. With reference to FIGS. 3 and 4, when the sacrificial gate structures 118 are formed, the dielectric layer 120 is formed on the side surfaces of the fins 114 and on exposed surfaces of the trench isolation region 116. Upon removal of the sacrificial gate layer 122, portions of the dielectric layer 120 are exposed on the top surfaces of the fins 114, on side surfaces of the fins 114, and on exposed portions of the trench isolation region 116. The portion 146a of the dielectric layer 146 is formed on the dielectric layer 120 that these locations. The portion 146b of the dielectric layer 146 corresponds to those portions of the dielectric layer 146 that are formed on the exposed side surfaces of the gate spacer layer 124.

As used herein, the suffixes “a”, “b”, and “c” are utilized with some reference numbers. The suffixes may be omitted when description is not particular to one of the portions or structures designated by the suffix.

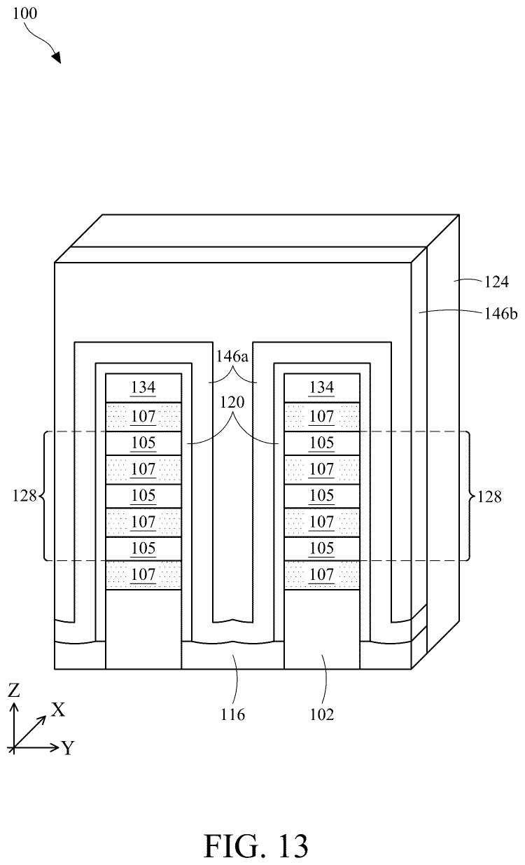

FIG. 13 is a perspective view of the integrated circuit 100 at the same stage of processing shown in FIG. 12, taken along cut lines 13 from FIG. 12, in accordance with some embodiments. In FIG. 13, and in subsequent figures, the semiconductor nanostructure 113 is not shown. However, in practice, the semiconductor nanostructure 113 is still present, in some embodiments.

The view of FIG. 13 illustrates that the portion 146a is on the dielectric layer 120 on exposed top surfaces and side surfaces of the fins 114 and on the exposed top surface of the trench isolation region 116. More particularly, the view of FIG. 13 illustrates that the dielectric layer 120 is formed on the top surface of the hard mask layer 134, the side surfaces of the hard mask layer 134, the side surfaces of the sacrificial semiconductor nanostructures 107, and the side surfaces of the channels 105. The dielectric layer 146 covers the dielectric layer 120 at these locations. The view of FIG. 13 also illustrates the portion 146b of the dielectric layer 146 covering side surfaces of the gate spacer layer 124.

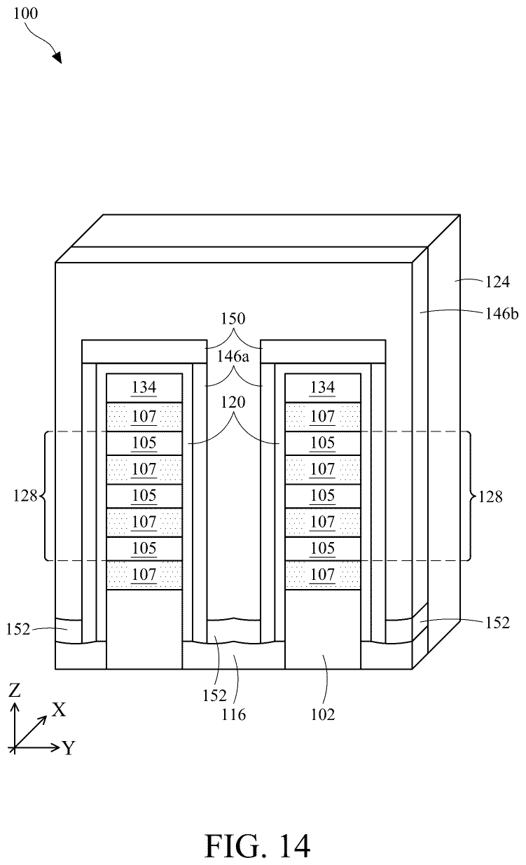

In FIG. 14, an ion implantation process is performed. The ion implantation process implants ions into the exposed horizontal surfaces of the dielectric layer 146. After the ion implantation process, a thermal annealing process is performed. The implantation of the ions into the exposed horizontal surfaces and the thermal annealing process result in the creation of a hard mask layer 150 and a hard mask layer 152 from the dielectric layer 146. The hard mask layer 150 covers the hard mask layer 134 and the stacked channels 105. The hard mask layer 152 covers a portion of the trench isolation region 116. In some embodiments, the ions include C, O, N, Si, Ge, F, or other suitable ions. As will be described in more detail below, in some embodiments F is used in the ion implantation of FIG. 14, F is also diffused into other structures in a separate diffusion process.

In some embodiments, the ion implantation process implants carbon and oxygen ions/atoms into the horizontal surfaces of the dielectric layer 146. The implantation of carbon and oxygen into the dielectric layer 146, combined with the thermal annealing process, results in the transformation of the material of the dielectric layer 146 into a new hard mask material. As described previously, in some embodiments, the dielectric layer 146 includes silicon nitride. The implantation of carbon and oxygen, combined with the thermal annealing process, results in a hard mask layer 150/152 of SiOCN. In some embodiments, only carbon ions or only oxygen ions are utilized in the implantation process. Other ions, atoms, or compounds can be utilized for the implantation process without departing from the scope of the present disclosure. Furthermore, other materials of the dielectric layer 146 can be utilized without departing from the scope of the present disclosure.

In some embodiments, the ion implantation process implants ions within energy between 0.01 kV and 100 kV. In some embodiments, the ion implantation dosages between 1E12 and 1E18. In some embodiments, the ion implantation process results in concentrations of implanted ions between 1E12 cm\hat{ }-3 and 1E16 cm\hat{ }-3. Other energies and concentrations can be utilized without departing from the scope of the present disclosure. Furthermore, the implanted regions may swell or otherwise change shape, as will be set forth in more detail below. The ions may diffuse into the dielectric layer 120 or into the trench isolation region 116. In practice, this has little impact on the function of these layers.

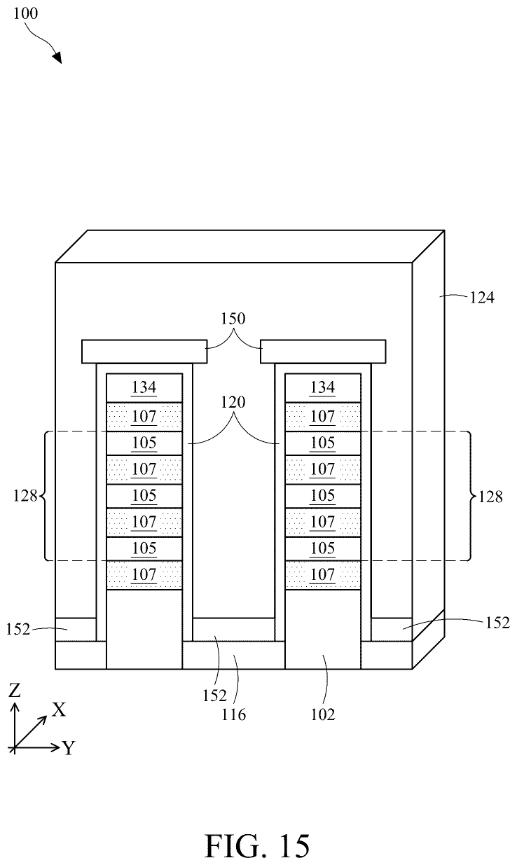

In FIG. 15, an etching process has been performed, in accordance with some embodiments. The etching process substantially removes the dielectric layer 146. The hard mask layer 150/152 are not removed. The sidewalls of the gate spacer layer 124 are exposed. In some embodiments, the etching process includes phosphoric acid.

Though not shown in FIG. 15, a subsequent etching process is also performed to remove the portions of the dielectric layer 120 that are not directly covered by the hard mask layer 150/152. Accordingly, this removal process exposes sidewalls of the hard mask layer 134, the sacrificial semiconductor nanostructures 107, and the channels 105. A portion of the dielectric layer 120 remains directly below the hard masks 150/152.

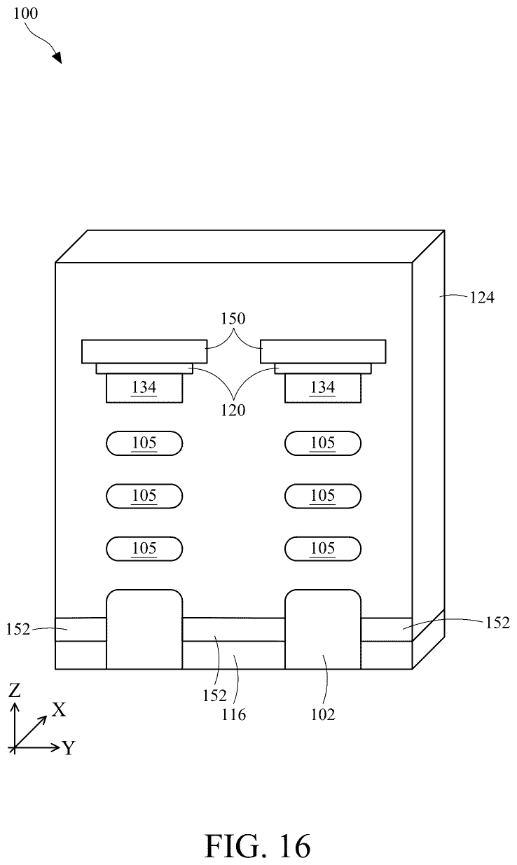

In FIG. 16, an etching process has been performed to remove the sacrificial semiconductor nanostructures 107, in accordance with some embodiments. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like. In some embodiments, the etching process results in a rounding of side surfaces of the channels 105. The etching process also results in gaps between the channels 105 and between the top channel 105 and the hard mask layer 134.

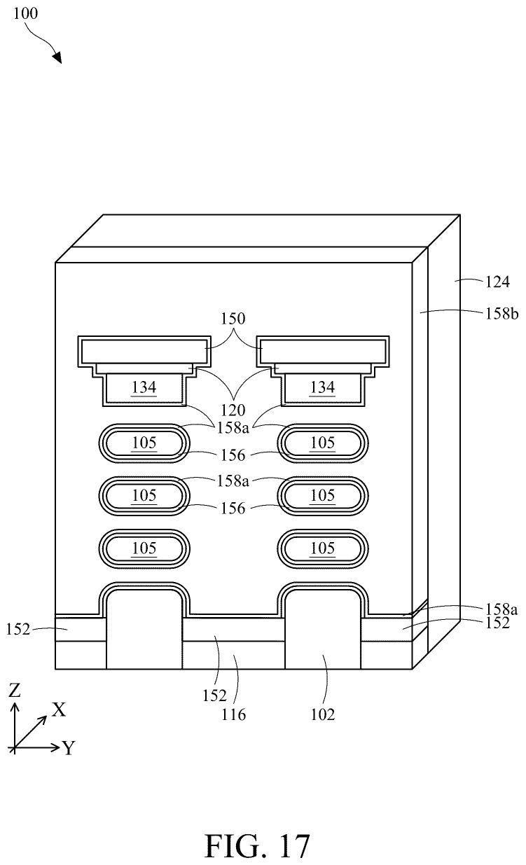

In FIG. 17, a gate dielectric has been formed, in accordance with some embodiments. The gate dielectric includes an interfacial gate dielectric layer 156 and a high-K gate dielectric layer 158. The interfacial gate dielectric layer 156 has been deposited on exposed portions of the channels 105 and sidewall spacers 124, in accordance with some embodiments. The interfacial gate dielectric layer 156 forms directly on the exposed portions of the channels 105. The high-K gate dielectric layer 158 forms on the interfacial gate dielectric layer 156 and on other exposed surfaces, such as the exposed sidewalls of the gate spacer layer 124, the exposed surfaces of the hard mask layer 134, exposed surfaces of the dielectric layer 120, and exposed surfaces of the hard masks 150/152.

The interfacial gate dielectric layer 156 is wrapped around the channels 105. The interfacial gate dielectric layer 156 can include a dielectric material such as silicon oxide, silicon nitride, or other suitable dielectric materials. The interfacial gate dielectric layer 156 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 156 can be formed by a thermal oxidation process, a chemical vapor deposition (CVD) process, or an atomic layer deposition (ALD) process. The interfacial gate dielectric layer 156 can have a thickness between 0.5 nm and 2 nm. Other materials, deposition processes, and thicknesses can be utilized for the interfacial gate dielectric layer 156 without departing from the scope of the present disclosure.

The high-K gate dielectric layer 158 is deposited in a conformal deposition process. The conformal deposition process deposits the high-K gate dielectric layer 158 on the interfacial gate dielectric layer 156, on the substrate 102, on the trench isolation regions 116, and on the gate spacer layer 124. The high-K gate dielectric layer 158 is wrapped around the channels 105. The high-K gate dielectric layer 158 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 158 may be formed by CVD, ALD, or any suitable method. Other thicknesses, deposition processes, and materials can be utilized for the high-K gate dielectric layer 158 without departing from the scope of the present disclosure.

As can be seen in FIG. 17, the high-K gate dielectric layer 158 includes a first portion 158a that forms on exposed surfaces of the hard mask layer structures 150/152, exposed surfaces of the dielectric layer 120, exposed surfaces of the hard mask layer 134, and exposed surfaces of the interfacial gate dielectric layer 156. The high-K gate dielectric layer 158 includes a second portion 158b that forms on exposed sidewalls of the gate spacer layer 124.

The dielectric layer 158 covers a large area and may have a relatively large thickness. As will be set forth in more detail below, eventually a gate metal will be formed in place of the sacrificial gate layer 122. The presence of the dielectric layers 120 and 158 adjacent to the gate metal can result in a relatively large gate to drain capacitance. As described previously, with the use of the hard mask structures 150/152, much of the dielectric layer 120 has already been removed. As will be set forth in more detail below, embodiments of the present disclosure utilize hard mask layers 150 to remove portions of the dielectric layer 158. This results in a reduced gate to drain capacitance and better performance of transistors.

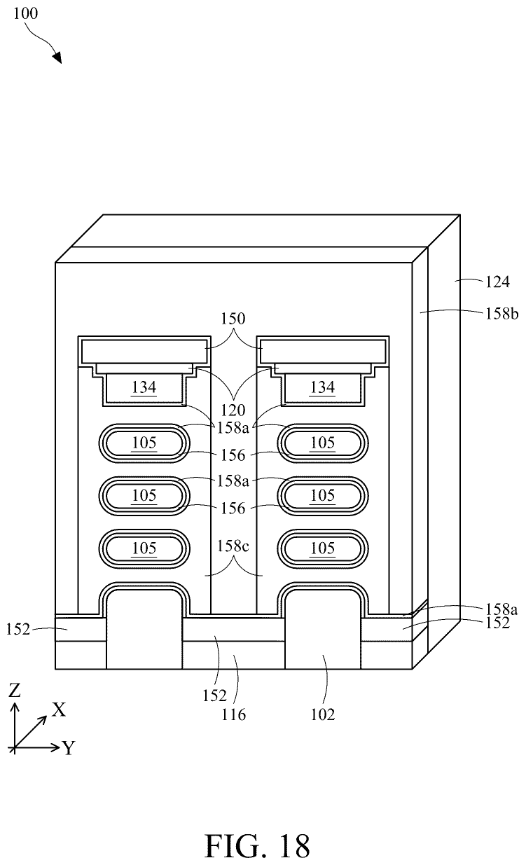

In FIG. 18, a bottom antireflective coating (BARC) layer has been deposited, in accordance with some embodiments. In some embodiments, the BARC layer 159 is deposited as part of a photolithography process. The BARC layer 159 can correspond to an organic polymer or dielectric layer. Initially, when the BARC layer 159 is deposited, the BARC layer 159 fills the space previously occupied by the sacrificial gate layer 122. The BARC layer 159 also fills the space below the hard mask structures 150, including the gaps between channels 105.

In FIG. 18, an etching process has been performed. The etching process removes the BARC layer 159 from all locations except for those below the mask structures 150 and the portion of the high-K gate dielectric layer 158 on sidewalls of the mask structures 150. Accordingly, in FIG. 18, the BARC layer 159 remains below the mask structures 150. In FIG. 18, the sides of the BARC layer 159 have substantially vertical sidewalls. As will be set forth in more detail below, the sidewalls of the BARC layer 159 can have angles other than vertical.

In FIG. 18, a sub-portion 158c of the portion 158b of the high-K gate dielectric layer 158 is covered by the remaining portion of the BARC layer 159 accordingly, the portion 158c is part of the portion 158b positioned on sidewalls of the gate spacer layers 134.

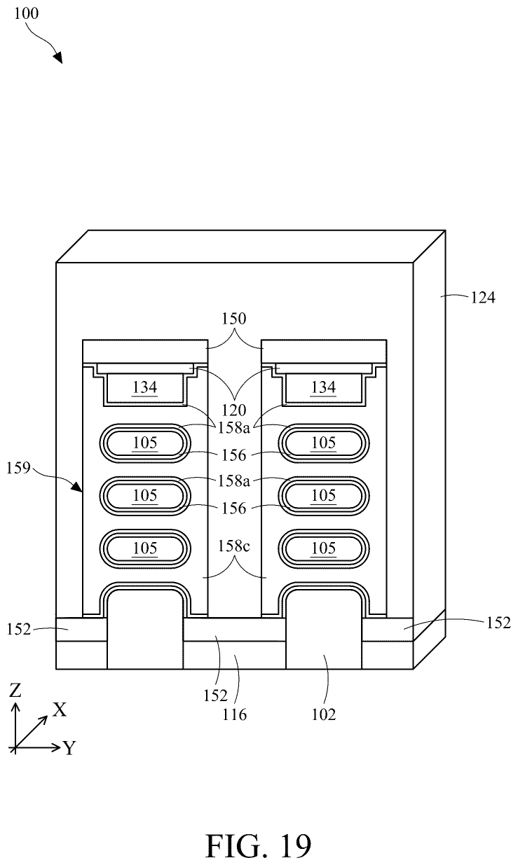

In FIG. 19, an etching process has been performed, in accordance with some embodiments. The etching process selectively etches the material the high-K gate dielectric layer 158. The result of the etching process is that the high-K gate dielectric layer 158 is removed at all locations except those covered by remaining portion of the BARC layer 159. Accordingly, the high-K gate dielectric layer 158 is removed, apart from the portions directly below the hard mask structures 150. The portion 158b is removed, with the exception of the sub-portion 158c. Accordingly, the high-K gate dielectric layer 158 remains on the sidewalls of the gate spacer layers 124 only below the hard mask structures 150.

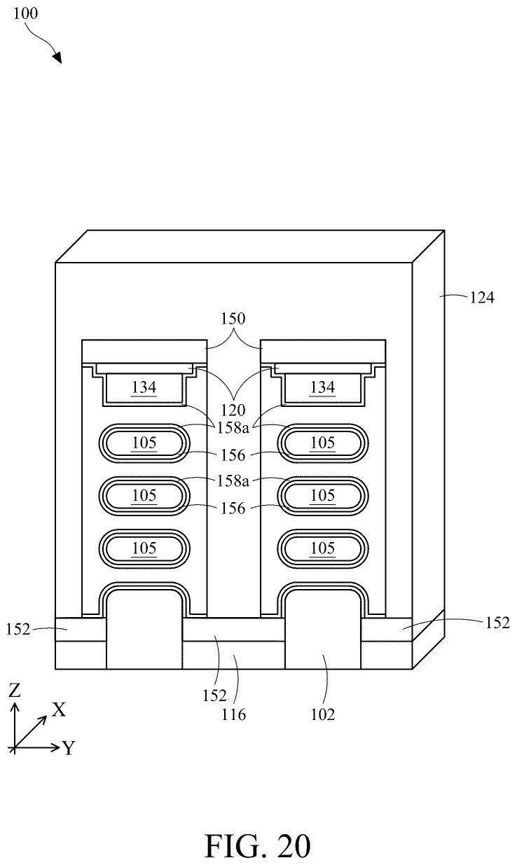

In FIG. 20, the portions 158a and 158c of the high-K gate dielectric layer 158 are exposed after removal of the BARC layer 159, in accordance with some embodiments. In FIG. 20, dopant atoms have also been implanted into the exposed dielectric structures. For example, the dopant atoms can be implanted into the remaining portion of the dielectric layer 20, the inner spacers 136, the remaining portion of the high-K gate dielectric layer 158, and other structures. In some embodiments, the end of a channel 105 and an edge of the hard mask layer 150 is between 1.5 nm and 20 nm. In some embodiments, if the extension is greater than 20 nm, then the high-K gate dielectric 158 of adjacent stacks may join.

In some embodiments, the dopant atoms include fluorine (F). The fluorine can be implanted by flowing a gas that contains fluorine into a furnace tube in which the integrated circuit 100 is positioned. In some embodiments, the fluorine can be implanted by soaking the integrated circuit with a fluorine gas. In some embodiments, the fluorine can be implanted via a high-energy implantation process. The result is that there is an increase concentration of fluorine in one or more of the high-K gate dielectric 158, the interfacial gate dielectric layer 156, the inner spacers 136, the dielectric layer 120, the hard mask structures 150/152, the gate spacer layers 124, and other exposed structures. In some embodiments, the concentration of fluorine (or other selected dopant species) is between 1% and 10%. The concentration greater than 1% begins to provide a beneficial reduction in the dielectric constant. The concentration of flooring greater than 10% is difficult to achieve. 0.2 and 2.0.

In some embodiments, the fluorine is infused into the hard mask layer 152. The hard mask layer 152 can include SiN, SiCN, SiOCN, SiON, or other suitable materials. The flooring concentration may be between 1% and 10%. The thickness of the hard mask layer 153 may be between 1 nm and 10 nm. The hard mask layer 153 can ensure that the trench isolation region 116 is not damaged or removed. In some embodiments, a portion of the high-K gate dielectric layer remains on the hard mask layer 152.

In some embodiments, the hard mask layer 134 includes SiN, SiCN, SiOCN, SiON or other suitable dielectric materials. In some embodiments, the hard mask layer 150 includes SiN, SiCN, SiOCN, or other suitable dielectric materials. In some embodiments, the hard mask layer 150 includes a concentration of fluorine between 1% and 10%. In some embodiments, the dielectric layer 120 has a thickness between 1 nm and 5 nm. In some embodiments, the hard mask layer 134 has a thickness between 1 nm and 10 nm. In some embodiments, the hard mask layer 150 has a thickness between 1 nm and 10 nm. In some embodiments, the hard mask layer 150 protrudes the on the edge of the hard mask layer 134 by distance between 0 nm. In some embodiments, the variation between the left and right overhang is less than 1 nm. In some embodiments, the vertical distance between adjacent channels 105 is between 5.5 nm and 15 nm. In some embodiments, the gate length in the X direction between adjacent gate spacers 124 is between 8 nm and 15 nm. The gate length in the X direction above the hard mask structure may be the same or different than the gate length in the X direction between channels 105. In some embodiments, the distance to turn adjacent stacks of channels in the Y direction is between 20 nm and 60 nm.

In some embodiments, an annealing process is performed after fluorine implantation. The annealing process can further repair traps and defects in the interfacial dielectric layer 156 and the high-K gate dielectric layer 158. In some embodiments, the annealing process is between 400° C. and 1000° C. The annealing process can include a soaking anneal between 400° C. and 500° C. for several minutes, with a temperature spiked therein between 700° C. and 800° C. for a duration between 1 ms and 10 seconds. Other temperatures and durations can be utilized without departing from the scope of the present disclosure. The fluorine implantation is performed at the same time as the annealing process, in some embodiments.

In some embodiments, the presence of fluorine dopants in the various dielectric structures, reduces the dielectric constant (K-value) of those dielectric structures. This can help reduce the parasitic capacitance between subsequently formed gate metals and source/drain contacts or source/drain regions 138.

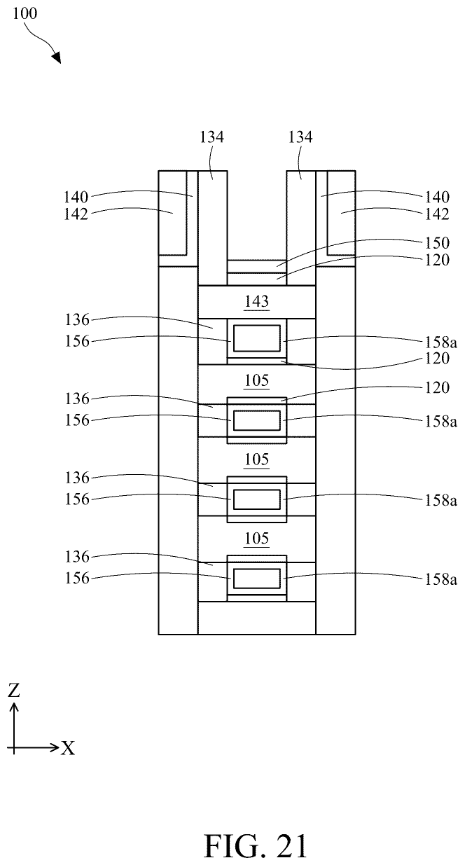

FIG. 21 is a cross-sectional view of the integrated circuit 100 at the stage of processing shown in FIG. 20, as FIG. 12, in accordance with some embodiments. FIG. 21 illustrates fluorine implanted gate spacer layers 134, the hard nanostructures 150, the dielectric layer 120, and other locations. FIG. 21 also illustrates the interfacial dielectric layer 156 and the high-K gate dielectric layer 158 wrapped around the channels 105. A gap is present between the channels 105 resulting from removal of the sacrificial semiconductor nanostructures 107, as described previously. Other dopant atoms or compounds can be implanted without departing from the scope of the present disclosure. As can be seen in FIG. 21, the high-K gate dielectric layer 158 is not present gate spacer layers 134 above the hard mask layer 150 and the gate trench 144.

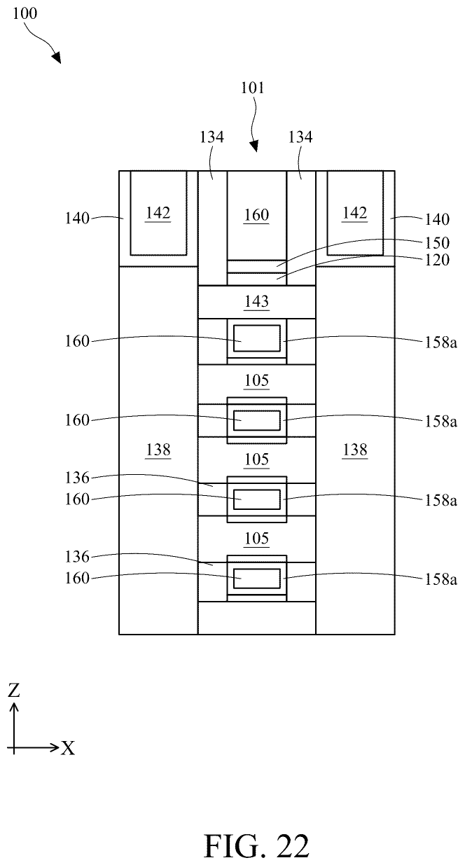

In FIG. 22, a gate metal 160 has been deposited, in accordance with some embodiments. The gate metal 160 is deposited in place of the sacrificial gate layer 122 and the sacrificial semiconductor nanostructures 107. Accordingly, the gate metal 160 is positioned in the gate trench 144 above the hard mask layer 134 and the above the hard mask layer 150. The gate metal 160 is also wrapped around the channels 105. The gate metal 160 is also wrapped around the combined structure of the hard mask layer 150, the dielectric layer 120, and the hard mask layer 134.

In FIG. 22, a single gate metal 160 is illustrated as a gate electrode of a transistor 101. However, in practice, the gate metal 160 can include multiple gate metals. For example, the gate metal 160 can include one or more liner layers, one or more work function layers, and a gate fill material that fills the remaining spaces between and the trench 140. The gate metal 160 can include one or more of Ti, TiN, Ta, TaN, Al, Cu, Co, Ru, W, Au, or other suitable conductive materials. The gate metal 160 can be deposited by PVD, ALD, or CVD.

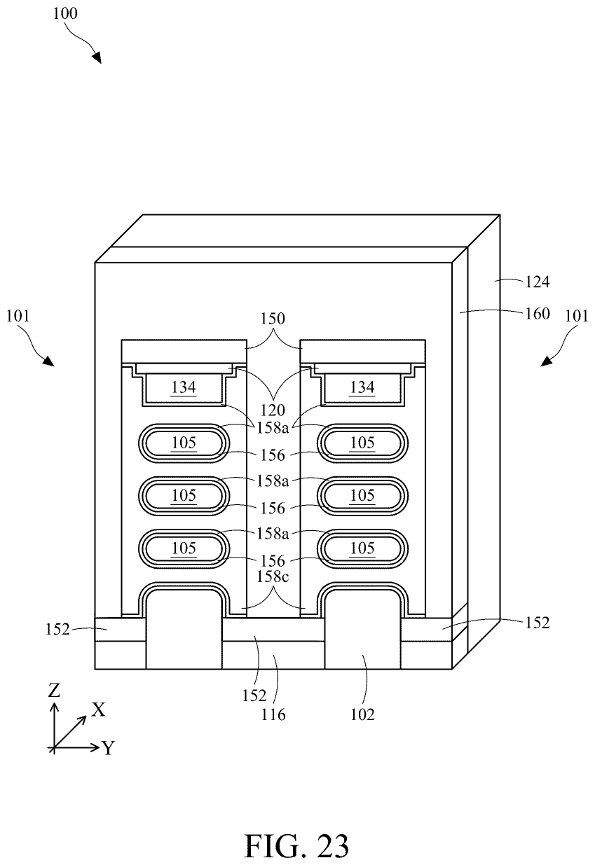

FIG. 23 is a perspective view of the integrated circuit 100 at the stage of processing shown in FIG. 22, from the same view as FIGS. 13-20, in accordance with some embodiments. FIG. 23 illustrates the gate metal 160 wrapped around the channels 105 and filling the space between adjacent stacks 128 of channels 105. FIG. 23 illustrates the stacks 128 of two different transistors 101. FIG. 23 also illustrates the gate metal positioned on side surfaces of the hard mask structures 150 and on all exposed surfaces of the high-K gate dielectric layer 158. The gate metal 160 is also positioned on the hard mask structures 152.

FIG. 23 illustrates, in dashed lines, the locations at which the high-K gate dielectric layer 128 is present between the gate spacer layer 124 and the gate metal 160. As set forth previously, the high-K gate dielectric layer 158 has been removed from sidewalls of the gate spacer layers 124 at locations outside of the previous covering of the park layer 159. Therefore, a substantial portion of the gate dielectric layer 150 has been removed. A large reduction in capacitance between the gate metal 160 and source/drain regions 138 and between the gate metal 160 and source/drain contacts (not shown). This provides transistors 101 with increased switching speed and higher overall performance. Furthermore, the implantation of fluorine into the various dielectric structures reduces dielectric constant and a corresponding reduction in parasitic capacitance. The distance between source/drain contacts and the gate metal 160 can further be increased by utilizing thicker low-K gate spacers 124 in place of the high-K gate dielectric layer 158b. Embodiments of the present disclosure can also enable further scaling by reducing the gate length in the X direction.

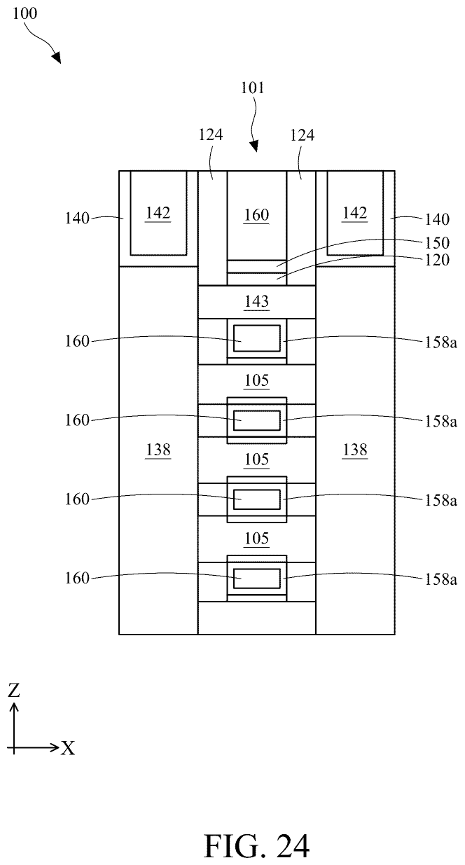

FIG. 24 is a cross-sectional view of the integrated circuit 100 at the stage of processing shown in FIG. 22, but without fluorine implantation (or other dopant species) in the gate spacers 134 in accordance with some embodiments. The fluorine implantation is primarily in the high-K gate dielectric layer 158. Accordingly, the high-K gate dielectric layer 158 has a higher concentration of fluorine (or other dopant species) than does the gate spacer layers 134.

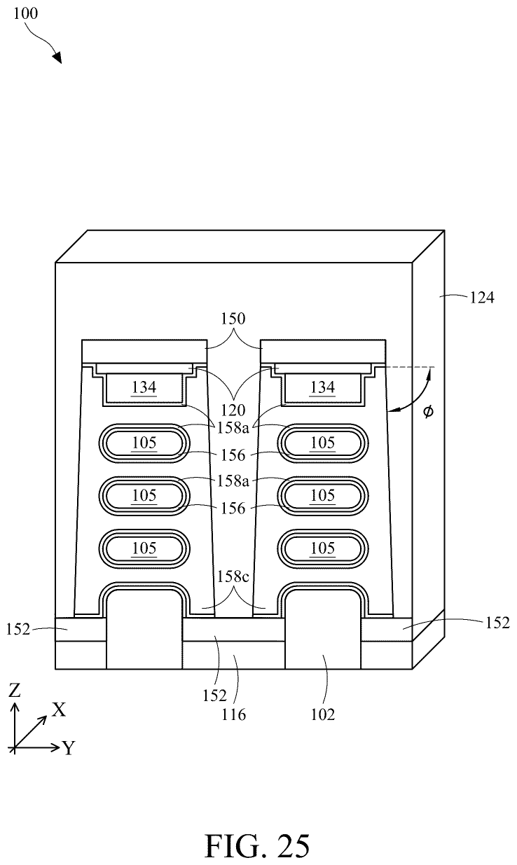

FIG. 25 is a cross-sectional view of an integrated circuit 100 at the stage of processing shown in FIG. 20, in accordance with some embodiments. The profile of the portion 158c of the high-K gate dielectric layer 158 is different than FIG. 25 and the FIG. 20. Particular, the edge of the portion 158c of the high-K gate dielectric layer 158 makes an angle theta with respect to horizontal. In some embodiments, the angle theta is between 60° and 90°, though other angles can be utilized without departing from the scope of the present disclosure. This angle can be achieved by performing the ion implantation with a selected angle relative to vertical.

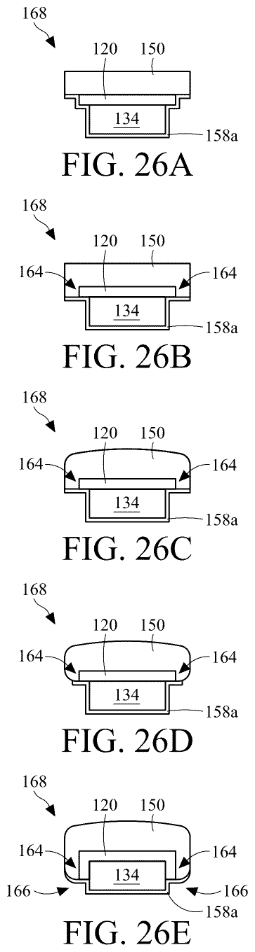

FIGS. 26A-26E are cross-sectional views of hard mask structures 168, in accordance with some embodiments. Each hard mask structure includes the hard mask layer 134, the dielectric layer 120, and the hard mask layer 150, in accordance with some embodiment.

In FIG. 26A, the hard mask layer 150 has a planar bottom surface above the top surface of the dielectric layer 120 and does not include a portion that protrudes downward on side surfaces of the dielectric layer 120. The result is that the high-K gate dielectric layer 158 has a double step structure 162 at the corner of the dielectric layer 120.

In some embodiments, the high-K gate dielectric layer 158 has a thickness between 0 nm and 2 nm. Though not shown in FIG. 23, in some embodiments, a portion of the high-K gate dielectric layer 158 may remain on top of the hard mask layer 150 with a vertical thickness less than the vertical thickness of the high-K gate dielectric layer 150 below the hard mask layer 134. In some embodiments, the high-K gate dielectric 158 may extend laterally further than a bottom corner of the hard mask layer 150. In some embodiments, the sidewall of the high-K gate dielectric layer 150 a is flush with a sidewall of the hard mask layer 150.

In FIG. 26B, the hard mask layer 150 includes a downward protrusion 164 that contacts sidewalls of the dielectric layer 120, in accordance with some embodiments. Accordingly, the top surface of the high-K gate dielectric layer 158 is substantially coplanar with a top surface of the hard mask layer 134.

In FIG. 26C, the hard mask layer 150 includes a convex top surface and vertically downward protruding portions 164, in accordance with some embodiments.

In FIG. 26D, the hard mask layer 150 has a convex top surface and downward protruding portions 164 that have curved side surfaces, in accordance with some embodiments.

In FIG. 26E, the dielectric layer 120 partially cover sidewalls of the hard mask layer 134, in accordance with some embodiments. Furthermore, the high-K gate dielectric layer 158 includes curved portions 166 on the curved downward protruding portions 164 of the hard mask layer 150. The top surface of the high-K gate dielectric layer 158 is lower than the top surface of the hard mask layer 134.

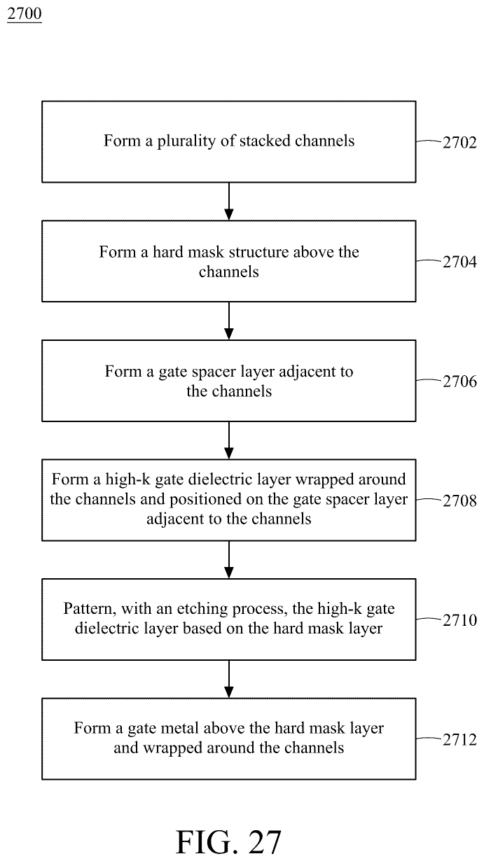

FIG. 27 is a flow diagram of a method 2700 for forming an integrated circuit, in accordance with some embodiments. The method 2700 can utilize the structures, processes, and systems described in relation to FIGS. 1-26E. At 2702, the method 2700 includes forming a plurality of stacked channels. One example of a plurality of stacked channels of the channels 105 of FIG. 18. At 2704, the method 2700 includes forming a hard mask structure above the channels. One example of a hard mask structure is the hard mask structure 168 of FIG. 26A. At 2706, the method 2700 includes forming a gate spacer layer adjacent to the channels. One example the gate spacer layer is the gate spacer layer 124 of FIG. 19. At 2708, the method 2700 includes forming a high-K gate dielectric layer wrapped around the channels and positioned on the gate spacer layer adjacent to the channels. One example of a high-K gate dielectric layer is the high-K gate dielectric layer 158 of FIG. 18. At 2710, the method 2700 includes patterning, with an etching process, the high-K gate dielectric layer based on the hard mask layer. at 2712, the method 2700 includes forming a gate metal above the hard mask layer and wrapped around the channels. One example of a gate metal is the gate metal 160 of FIG. 23.

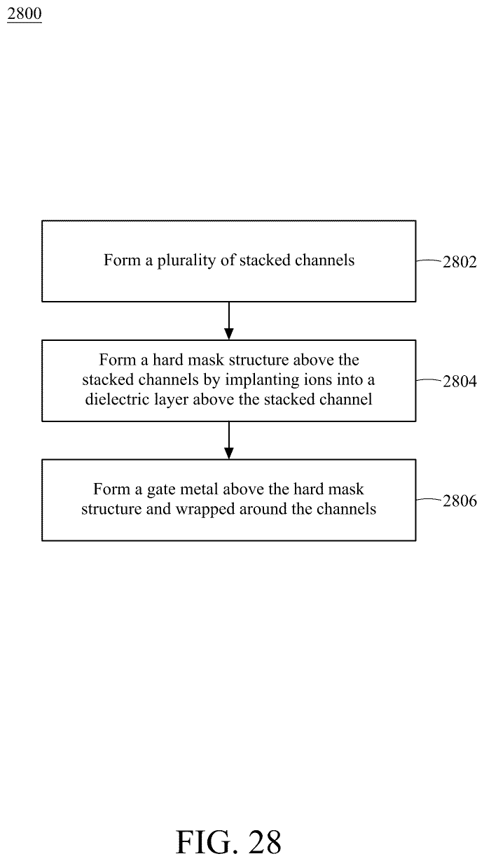

FIG. 28 is a flow diagram of a method 2800 for forming an integrated circuit, in accordance with some embodiments. The method 2800 can utilize the structures, processes, and systems described in relation to FIGS. 1-26E. At 2802, the method 2800 forming a plurality of stacked channels. One example of stacked channels of channels 105 of FIG. 18. At 2804, the method 2800 includes forming a hard mask structure above the stacked channels by implanting ions into a dielectric layer above the stacked channel. One example of a dielectric layer is the dielectric layer 146 of FIG. 13. One example of a hard mask structure is the hard mask structure 168 of FIG. 26A. At 2806, the method 2800 includes forming a gate metal above the hard mask structure and wrapped around the channels. One example of a gate metal is the gate metal 160 of FIG. 23.

Embodiments of the disclosure provide nanostructure transistors with reduced gate to source/drain capacitance. Embodiments of the present disclosure provide a hard mask structure above the stacked channels of a transistor. The hard nanostructures utilized to remove the high-K gate dielectric layer from sidewalls of a gate spacer layer, apart from below the hard mask structure. Furthermore, dopant atoms are implanted into dielectric structures adjacent to the gate metal to further reduce the dielectric constant of those dielectric structures. The result is that gate capacitances are greatly reduced. This further results in transistors that can operate at higher frequencies, have superior electrical characteristics, and better overall performance. Furthermore, this can improve wafer yields and overall function of integrated circuits and electronic devices in which the integrated circuits are embedded.

In some embodiments, a device includes a plurality of stacked channels, a hard mask structure above the channels, and a gate metal above the hard mask structure and wrapped around the channels. The device includes a high-K gate dielectric layer wrapped around the channels. A top of the hard mask structure is higher than a top of the high-K gate dielectric layer.

In some embodiments, a method includes forming a plurality of stacked channels, forming a hard mask structure above the channels, and forming a gate spacer layer adjacent to the channels. The method includes forming a high-K gate dielectric layer wrapped around the channels and positioned on the gate spacer layer adjacent to the channels, patterning, with an etching process, the high-K gate dielectric layer based on the hard mask layer, and forming a gate metal above the hard mask layer and wrapped around the channels.

In some embodiments, a method includes forming a plurality of stacked channels and forming a hard mask structure above the stacked channels by implanting ions into a dielectric layer above the stacked channel. The method includes forming a gate metal above the hard mask structure and wrapped around the channels.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a plurality of stacked channels;
a hard mask structure above the channels;
a gate metal above the hard mask structure and wrapped around the channels; and
a high-K gate dielectric layer wrapped around the channels, wherein a top of the hard mask structure is higher than a top of the high-K gate dielectric layer.

2. The device of claim 1, wherein the gate metal is wrapped around the hard mask structure.

3. The device of claim 1, comprising a gate spacer layer adjacent to the gate metal, wherein the high-K gate dielectric layer includes a portion positioned on the gate spacer layer below the hard mask structure.

4. The device of claim 3, wherein a sidewall of the portion of the high-K gate dielectric layer is substantially vertical.

5. The device of claim 3, wherein a sidewall of the portion of the high-K gate dielectric layer makes an angle relative to vertical, wherein the angle is between 0 degrees and 30 degrees.

6. The device of claim 1, wherein the hard mask structure includes:
a first hard mask layer above the stacked channels; and
a second hard mask layer above the first hard mask layer.

7. The device of claim 6, wherein the hard mask structure includes a dielectric layer positioned between the first and second hard mask layers.

8. The device of claim 7, wherein the second hard mask layer covers a sidewall of the dielectric layer.

9. The device of claim 6, wherein the second hard mask layer has a curved bottom surface.

10. The device of claim 6, wherein the high-K gate dielectric layer is in contact with a bottom surface of the first hard mask layer and a bottom surface of the second hard mask layer.

11. The device of claim 3, wherein the gate spacer layer includes fluorine.

12. The device of claim 1, wherein the high-K gate dielectric layer includes fluorine.

13. A method, comprising:
forming a plurality of stacked channels;
forming a hard mask structure above the channels;
forming a gate spacer layer adjacent to the channels;
forming a high-K gate dielectric layer wrapped around the channels and positioned on the gate spacer layer adjacent to the channels;
patterning, with an etching process, the high-K gate dielectric layer based on the hard mask layer; and
forming a gate metal above the hard mask layer and wrapped around the channels.

14. The method of claim 13, wherein patterning the high-K gate dielectric layer includes removing the high-K gate dielectric layer from the gate spacer layer above the hard mask layer, wherein the high-K gate dielectric layer remains on the gate spacer layer below the hard mask structure after the etching process.

15. The method of claim 13, comprising:
depositing a bottom anti-reflective coating on the high-K gate dielectric layer before patterning the high-K gate dielectric layer;
removing a first portion of the bottom anti-reflective coating above the hard mask structure;
performing the etching process after removing the first portion of the bottom anti-reflective coating; and
removing a remainder of the bottom anti-reflective coating after performing the etching process.

16. The method of claim 13, comprising infusing fluorine into the high-K gate dielectric layer after patterning the high-K gate dielectric layer.

17. The method of claim 16, comprising infusing fluorine into the gate spacer layer after patterning the high-K gate dielectric layer.

18. A method, comprising:
forming a plurality of stacked channels;
forming a hard mask structure above the stacked channels by implanting ions into a dielectric layer above the stacked channel; and
forming a gate metal above the hard mask structure and wrapped around the channels.

19. The method of claim 18, wherein the dielectric layer is SiN and the ions include one or both of C and O.

20. The method of claim 19, wherein the gate metal is positioned between the hard mask structure and a highest channel of the stacked channels.
